(19) United States
(12) Patent Application Publication
(10) Pub. No.: US 2023/0030509 A1
(43) Pub. Date: Feb. 2, 2023

(54) DATA PROCESSING APPARATUS, METHOD FOR PROCESSING DATA, AND STORAGE MEDIUM

(71) Applicant: CANON KABUSHIKI KAISHA, Tokyo (JP)

(72) Inventor: Yujiro Idaka, Tokyo (JP)

(21) Appl. No.: 17/815,360

(22) Filed: Jul. 27, 2022

(30) Foreign Application Priority Data
Jul. 30, 2021 (JP) 2021-125989

(51) Int. Cl. H03G 3/30; H04N 5/232

(52) U.S. Cl. CPC H03G 3/3005; H04N 5/232; G10L 21/034

(57) ABSTRACT

A data processing apparatus includes one or more processors, and one or more memories including instructions stored thereon that, when executed by the one or more processors, cause the data processing apparatus to function as a copy unit configured to generate second sound data by copying first sound data, and a processing unit configured to apply a first gain to at least one of the first sound data and the second sound data.

### BACKGROUND OF THE DISCLOSURE

### Field of the Disclosure

The present disclosure relates to a data processing apparatus, a method for processing data, and a storage medium.

### Description of the Related Art

A camera controlled via a network, a dedicated line, a remote controller, or the like may be provided with a voice input function. The voice input function includes an automatic gain control (AGC) function that automatically adjusts a gain so that a voice level is always at an appropriate volume level. If a loud voice is input, the gain is decreased, and if a small voice is input, the gain is increased by the AGC function.

Among functions installed in a camera that is provided with the voice input function, there is a plurality of voice recognition functions that are analysis functions using voice (e.g., occurrence of an event is recognized if a sound volume exceeding a set value is input). In a case where the gain is changed by the AGC function, the analysis functions using voice may not normally function.

In Japanese Patent Application Laid-Open No. 5-336590, a technique is discussed in which a noise generated by an engine and a frequency thereof are estimated from an engine rotation speed, and a band-pass filter is applied to reduce the noise in order to prevent an engine sound, which is a background sound, from being amplified by the AGC function.

In Japanese Patent No. 5817368, a technique for turning off the AGC function in a case where an application using voice recognition is to be executed on an amplified voice signal is discussed.

However, according to the technique discussed in Japanese Patent Application Laid-Open No. 5-336590, if the band-pass filter is applied to reduce the noise generated by the engine, a voice level that is originally intended to be obtained in the same frequency band as that of the noise is reduced. Thus, in a case where a voice intended to be detected is in the same frequency band as that of the noise, detection performance in voice analysis deteriorates.

According to the technique discussed in Japanese Patent No. 5817368, the AGC function is turned off at the time when the application using voice recognition is executed, so that a sound volume of voice distribution may be too loud and saturated, or too small to be heard.

### SUMMARY OF THE DISCLOSURE

According to an aspect of the present disclosure, a data processing apparatus includes one or more processors, and one or more memories including instructions stored thereon that, when executed by the one or more processors, cause the data processing apparatus to function as a copy unit configured to generate second sound data by copying first sound data, and a processing unit configured to apply a first gain to at least one of the first sound data and the second sound data.

Further features of the present disclosure will become apparent from the following description of exemplary embodiments with reference to the attached drawings.

### BRIEF DESCRIPTION OF THE DRAWINGS

FIG. 1 is a block diagram schematically illustrating a configuration example of a data processing apparatus according to a first exemplary embodiment.

FIG. 2 is a block diagram schematically illustrating a configuration example of an image capturing apparatus according to the first exemplary embodiment.

FIG. 3 is a block diagram illustrating a configuration example of the data processing apparatus according to the first exemplary embodiment.

FIG. 4 is a flowchart illustrating sound data copy processing according to the first exemplary embodiment.

FIG. 5 is a block diagram schematically illustrating a configuration example of a data processing apparatus according to a second exemplary embodiment.

FIG. 6 illustrates an example of gain setting of a data processing apparatus according to a third exemplary embodiment.

FIG. 7 is a block diagram illustrating a hardware configuration example of a data processing apparatus according to a fourth exemplary embodiment.

### DESCRIPTION OF THE EMBODIMENTS

Exemplary embodiments of the present disclosure will be described in detail below with reference to the attached drawings. The following exemplary embodiments are not intended to limit the present disclosure, and not all combinations of features described in the exemplary embodiments are essential for solving means of the present disclosure. Configurations of the exemplary embodiments can be appropriately modified or changed according to the specifications and various conditions (such as a use condition and a use environment) of an apparatus to which the present disclosure is applied. The technical scope of the present disclosure is defined by the claims and is not limited by the individual exemplary embodiments described below.

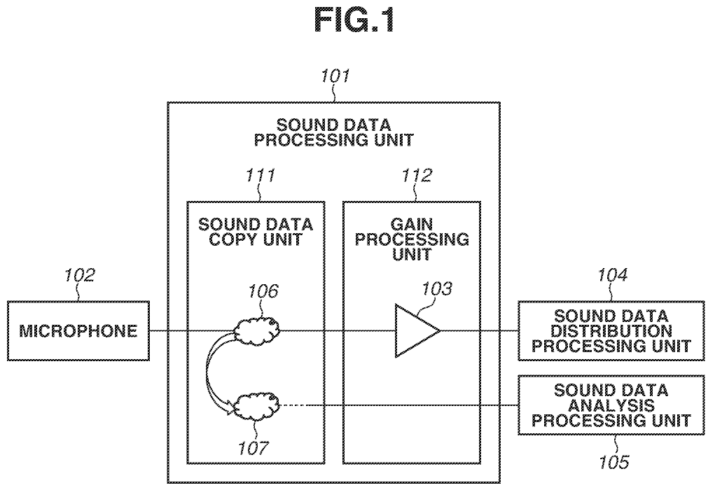

FIG. 1 is a block diagram schematically illustrating a configuration example of a data processing apparatus according to a first exemplary embodiment.

Regarding a function to be implemented by software in each function block illustrated in FIG. 1, a program for providing the function of each function block is stored in a memory such as a read only memory (ROM). Then, the program is read into a random access memory (RAM) and executed by a central processing unit (CPU), and thus the function is implemented. Regarding a function to be implemented by hardware, for example, a dedicated circuit may be automatically generated in a field programmable gate array (FPGA) from a program for implementing the function of each function block using a predetermined compiler. Alternatively, a gate array circuit may be formed in the same manner as the FPGA so that the function is implemented as hardware. The function may also be implemented by an application specific integrated circuit (ASIC). The configuration of the function blocks illustrated in FIG. 1 is an example. A plurality of function blocks may form one function block, or any of the function blocks may be divided into blocks that perform a plurality of functions.

In FIG. 1, the data processing apparatus includes a sound data processing unit 101, a sound data distribution processing unit 104, and a sound data analysis processing unit 105. The sound data processing unit 101 includes a sound data copy unit 111 and a gain processing unit 112. The gain processing unit 112 includes an automatic gain control (AGC) unit 103.

The sound data processing unit 101 processes sound data input via a microphone 102, generates two pieces of sound data of which sound volumes are different from each other with respect to an input of the same sound, and outputs the two pieces of sound data respectively to the sound data distribution processing unit 104 and the sound data analysis processing unit 105. At that time, the sound data processing unit 101 can apply a gain to at least one of the two pieces of sound data. For example, the sound data processing unit 101 generates sound data to which an AGC gain is applied and sound data to which an AGC gain is not applied. Then, the sound data processing unit 101 can output the sound data to which the AGC gain is applied to the sound data distribution processing unit 104 and output the sound data to which the AGC gain is not applied to the sound data analysis processing unit 105.

The sound data copy unit 111 generates sound data 107 by copying sound data 106 input via the microphone 102.

The gain processing unit 112 outputs the sound data 106 after applying the AGC gain thereto and also outputs the sound data 107 without applying the AGC gain. The AGC unit 103 applies the AGC gain to the sound data 106.

The sound data distribution processing unit 104 distributes the sound data 106 to which the AGC gain is applied.

A network or a dedicated line may be used for distribution of the sound data 106 to which the AGC gain is applied. A distribution destination of the sound data 106 to which the AGC gain is applied is, for example, an information processing apparatus connected to an image capturing apparatus.

The sound data analysis processing unit 105 analyzes the sound data 107 to which the AGC gain is not applied. Analysis processing of the sound data 107 may include recognition processing and frequency analysis processing of the sound data 107. The recognition processing of the sound data 107 may include, for example, recognition processing of an abnormal sound such as a sound of shattering glass.

The gain processing unit 112 applies the AGC gain to the sound data 106 to be output to the sound data distribution processing unit 104 and thus can prevent a sound volume of the sound data 106 at a time of distribution from being too loud and saturated or being too small to be heard.

The gain processing unit 112 does not apply the AGC gain to the sound data 107 to be output to the sound data analysis processing unit 105 to prevent the data to be an analysis target from being suppressed and to suppress deterioration in analysis accuracy of the sound data 107. At that time, the sound data copy unit 111 copies the sound data 106 before the AGC gain is applied. Thus, it is possible to implement distribution of a sound picked up by the microphone 102 at an optimized sound volume while suppressing deterioration in the analysis accuracy.

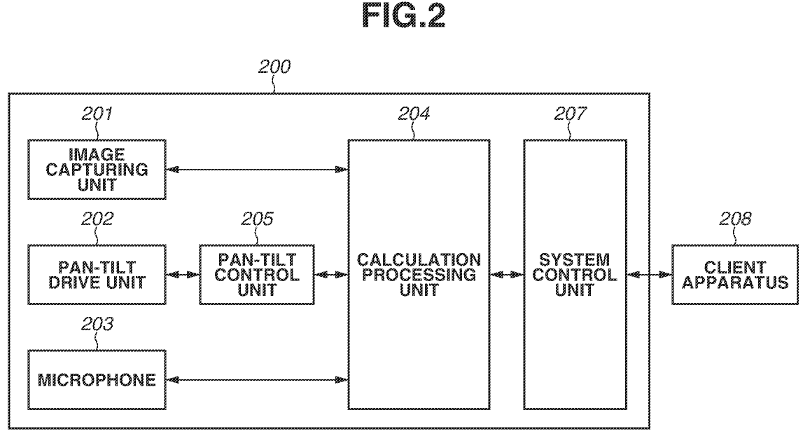

FIG. 2 is a block diagram schematically illustrating a configuration example of an image capturing apparatus according to the first exemplary embodiment. In FIG. 2, a pan-tilt camera equipped with a microphone is illustrated as an example of the image capturing apparatus. The image capturing apparatus can be used as, for example, a monitoring camera.

In FIG. 2, a camera 200 includes an image capturing unit 201, a pan-tilt drive unit 202, a microphone 203, a calculation processing unit 204, a pan-tilt control unit 205, and a system control unit 207.

The camera 200 is connected to a client apparatus 208 in a mutually communicable state. The client apparatus 208 is an information processing apparatus such as a personal computer.

A user can transmit various commands from the client apparatus 208 to the camera 200.

The image capturing unit 201 captures an image based on light from an object. At that time, the image capturing unit 201 converts the light focused on an image sensing surface into an electrical signal for each pixel and outputs the electrical signal to the calculation processing unit 204. The image capturing unit 201 includes image pickup lenses including a focus lens and a zoom lens, an image pickup element, and a mechanical drive system and a drive circuit that drive the image pickup lenses and image pickup element. The image pickup element is, for example, a charge coupled device (CCD) sensor or a complementary metal oxide semiconductor (CMOS) sensor.

The pan-tilt drive unit 202 performs pan (horizontal direction rotation) drive and tilt (vertical direction rotation) drive of the camera 200. The pan-tilt drive unit 202 includes a mechanical drive system that performs a pan-tilt operation, a motor that is a drive source, and a motor driver.

The calculation processing unit 204 performs image processing such as noise removal and gamma correction on the electrical signal converted by the image capturing unit 201, generates image data, and transmits the image data to the system control unit 207. The calculation processing unit 204 also processes a command received from the system control unit 207. For example, in a case where the calculation processing unit 204 receives an instruction to change a zoom position or a focus position from the system control unit 207, the calculation processing unit 204 drives the focus lens or the zoom lens to the instructed position. In a case where the calculation processing unit 204 receives an instruction to adjust image quality from the system control unit 207, the calculation processing unit 204 adjusts the image quality. Further, the calculation processing unit 204 performs a calculation related to pan-tilt position information to be transmitted to the pan-tilt control unit 205.

The calculation processing unit 204 also performs a calculation related to sound data input via the microphone 203 and performs sound data analysis processing. At that time, the calculation processing unit 204 can copy the sound data input via the microphone 203 and generate the sound data to which the AGC gain is applied and the sound data to which the AGC gain is not applied. Then, the calculation processing unit 204 can perform distribution processing on the sound data to which the AGC gain is applied and analysis processing on the sound data to which the AGC gain is not applied.

The pan-tilt control unit 205 processes a command related to pan-tilt control received by the calculation processing unit 204 via the system control unit 207 and controls the pan-tilt drive unit 202.

For example, the pan-tilt control unit 205 controls a drive amount, a speed, acceleration and deceleration of the pan-tilt drive unit 202 based on an instruction of the command related to the pan-tilt control and performs an initialization operation of the pan-tilt drive unit 202.

The system control unit 207 controls an entire pan-tilt camera 200. For example, the system control unit 207 distributes the image data generated by the calculation processing unit 204 to the client apparatus 208. Further, the system control unit 207 analyzes a camera control command transmitted from the client apparatus 208 and transmits a command related to the calculation processing unit 204 to the image capturing unit 201.

The system control unit 207 also transmits a response to the camera control command to the client apparatus 208.

The system control unit 207 distributes the sound data output from the calculation processing unit 204 to the client apparatus 208. At that time, the system control unit 207 may distribute the sound data picked up by the microphone 203 at the time of image capturing by the image capturing unit 201 together with the image data to the client apparatus 208. Alternatively, the system control unit 207 may distribute the sound data picked up by the microphone 203 alone to the client apparatus 208. Further, the system control unit 207 may notify the client apparatus 208 of occurrence of an event detected based on the analysis processing of the sound data to which the AGC gain is not applied. For example, in a case where a sound of shattering glass is detected based on the analysis processing of the sound data to which the AGC gain is not applied, the system control unit 207 may notify the client apparatus 208 of occurrence of the event.

The camera 200 according to the present exemplary embodiment is not limited to the configuration illustrated in FIG. 2. For example, the camera 200 may include a video output terminal such as a Serial Digital Interface (SDI) or a High-Definition Multimedia Interface (HDMI) (registered trademark). The camera 200 may further include a sound data input and output unit or an external device input and output unit.

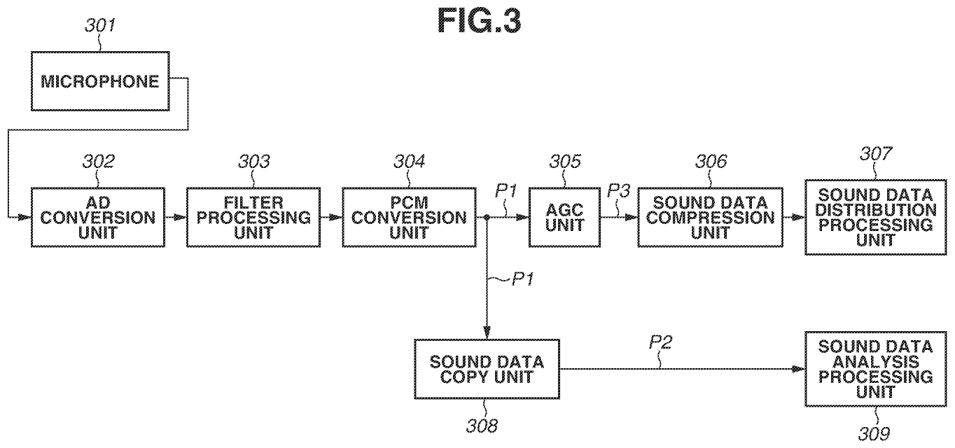

FIG. 3 is a block diagram illustrating a configuration example of the data processing apparatus according to the first exemplary embodiment.

In FIG. 3, the calculation processing unit 204 in FIG. 2 includes an analog-to-digital (AD) conversion unit 302, a filter processing unit 303, a pulse code modulation (PCM) conversion unit 304, an AGC unit 305, a sound data compression unit 306, and a sound data distribution processing unit 307. The calculation processing unit 204 further includes a sound data copy unit 308 and a sound data analysis processing unit 309.

The AD conversion unit 302 converts sound data acquired via a microphone 301 from an analog signal into a digital signal.

Next, the filter processing unit 303 cuts unnecessary high-frequency component and low-frequency component from the sound data converted into the digital signal.

Then, the PCM conversion unit 304 converts the sound data output from the filter processing unit 303 into a PCM signal and outputs converted sound data P1 to the AGC unit 305 and the sound data copy unit 308.

Then, the AGC unit 305 applies the AGC gain to the sound data P1 and generates sound data P3 in which a sound volume of the sound data P1 is optimized.

Then, the sound data P3 to which the AGC gain is applied is subjected to data compression by the sound data compression unit 306 to secure a bandwidth at the time of distribution, and the sound data P3 is distributed via the sound data distribution processing unit 307.

Meanwhile, the sound data copy unit 308 generates sound data P2 by copying the sound data P1 having been converted into the PCM signal. Then, the sound data P2 copied by the sound data copy unit 308 is transmitted to the sound data analysis processing unit 309 without being applied the AGC gain, and the sound data analysis processing unit 309 performs analysis processing on the sound data P2.

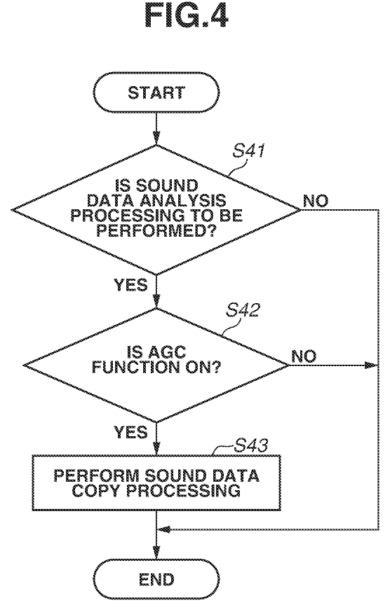

FIG. 4 is a flowchart illustrating sound data copy processing according to the first exemplary embodiment.

Each step in FIG. 4 is implemented by the calculation processing unit 204 reading a program stored in a storage unit in the camera 200 in FIG. 2 and executing the program. At least part of the processing in the flowchart in FIG. 4 may be implemented by hardware. In a case where the processing is implemented by hardware, for example, a dedicated circuit may be automatically generated in an FPGA from a program for implementing each step using a predetermined compiler. Alternatively, a gate array circuit may be formed in the same manner as the FPGA so that the processing is implemented as hardware. Alternatively, the processing may also be implemented by an ASIC.

In this case, each block in the flowchart illustrated in FIG. 4 can be regarded as a hardware block. A plurality of blocks may be collectively configured as one hardware block, or one block may be configured as a plurality of hardware blocks.

In FIG. 4, in step S41, the calculation processing unit 204 determines whether to perform sound data analysis processing. In a case where the sound data analysis processing is not to be performed (NO in step S41), the calculation processing unit 204 ends the processing. On the other hand, in a case where the sound data analysis processing is performed (YES in step S41), in step S42, the calculation processing unit 204 determines whether the AGC function is on. In a case where the AGC function is off (NO in step S42), the calculation processing unit 204 ends the processing. On the other hand, in a case where the AGC function is on (YES in step S42), in step S43, the calculation processing unit 204 performs sound data copy processing.

It is desirable that the processing in FIG. 4 be applied to a case where the sound data copy processing is executed on the hardware so that power consumption can be reduced. In a case where software processing or the like is adopted and there is little concern about an increase in the power consumption, the calculation processing unit 204 may always perform copy processing of the sound data input via the microphone 203.

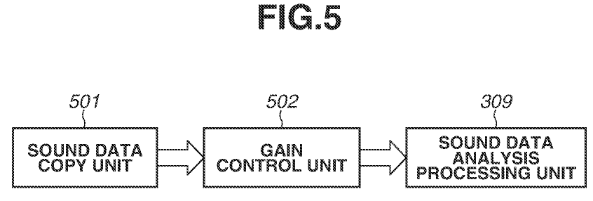

FIG. 5 is a block diagram schematically illustrating a configuration example of a data processing apparatus according to a second exemplary embodiment.

In FIG. 5, the data processing apparatus includes a sound data copy unit 501 and a gain control unit 502 instead of the sound data copy unit 308 in FIG. 3.

The sound data copy unit 501 copies sound data input via the microphone 301.

At that time, the sound data copy unit 501 may copy the sound data P1 to which the AGC gain has not been applied by the AGC unit 305 yet or may copy the sound data P3 to which the AGC gain has been applied by the AGC unit 305.

The gain control unit 502 can apply a gain different from the AGC gain to be applied by the AGC unit 305 to the sound data copied by the sound data copy unit 501. For example, the gain control unit 502 may store an AGC gain at the time of calibration and apply the AGC gain at the time of calibration to the sound data copied by the sound data copy unit 501. In a calibration period in which an internal setting of the sound data analysis processing is performed, the sound data P3 to which the gain has been applied by the AGC unit 305 is copied and used for the sound data analysis processing. At that time, the gain control unit 502 stores the AGC gain at the time of calibration and applies the same AGC gain after the calibration. In this case, the gain control unit 502 uses the sound data P1 to which the gain has not been applied by the AGC unit 305 yet for copying the sound data.

Accordingly, the gain control unit 502 can apply a constant gain stored during the calibration period to the sound data to be used in the sound data analysis processing. Thus, a sound volume of the sound data to be used in the sound data analysis processing can be optimized, and deterioration in accuracy of the sound data analysis processing can be suppressed.

The gain control unit 502 may use the sound data P3 to which the gain has been applied by the AGC unit 305 also after the calibration period. At that time, the gain control unit 502 may apply a negative gain having an opposite sign to the AGC gain to the sound data P3 in order to cancel the AGC gain applied by the AGC unit 305.

Accordingly, even in a system that cannot copy the sound data P1 to which the gain has not been applied by the AGC unit 305 yet and has to copy the sound data P3 to which the gain has been applied by the AGC unit 305, the sound data analysis processing unit 309 can analyze the sound data having a fixed gain.

The gain control unit 502 may change a detection threshold of the sound data P3 to which the gain has been applied by the AGC unit 305 in response to a change in the gain of the sound data P3. For example, in a case where the sound data analysis processing unit 309 detects a sound volume of the sound data P3 above a certain level, the gain control unit 502 can lower the detection threshold of the sound volume by the gain applied by the AGC unit 305.

Accordingly, in a case where an analysis target is changed and it is desirable to lower a detection level of the sound data analysis processing, the sound data analysis processing unit 309 can perform the sound data analysis processing while handling the gain applied by the AGC unit 305.

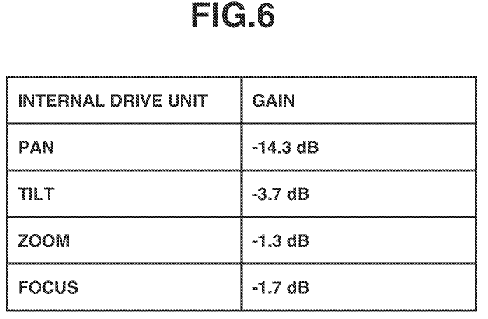

FIG. 6 illustrates an example of settings of gains in a data processing apparatus according to a third exemplary embodiment.

In FIG. 6, the gain control unit 502 in FIG. 5 applies a negative gain corresponding to each internal drive unit of the camera 200 in FIG. 2 to sound data during operation of internal drive units. The internal drive units of the camera 200 include, for example, a pan drive unit (Pan), a tilt drive unit (Tilt), and a zoom unit (Zoom) and a focus unit (Focus) of the image capturing unit 201. The negative gain can be set for each of the internal drive units. The negative gain can be set depending on loudness of a driving sound generated by each of the internal drive units during operation.

Accordingly, in a case where the internal drive units generate driving sounds during operation, the driving sounds overlapping the sound data used in the analysis processing can be reduced, and thus a malfunction of the sound data analysis processing due to internal noises of the camera 200 can be prevented.

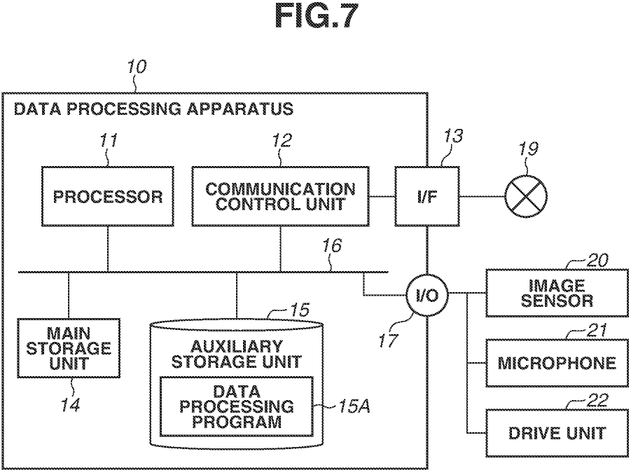

FIG. 7 is a block diagram illustrating a hardware configuration example of a data processing apparatus according to a fourth exemplary embodiment.

In FIG. 7, a data processing apparatus 10 can implement a function to be implemented by software in the camera 200 among the functions of the camera 200 in FIG. 2. At that time, the data processing apparatus 10 can implement the function of the calculation processing unit 204 in FIG. 1.

The data processing apparatus 10 includes a processor 11, a communication control unit 12, a communication interface 13, a main storage unit 14, an auxiliary storage unit 15, and an input and output interface 17. The processor 11, the communication control unit 12, the communication interface 13, the main storage unit 14, the auxiliary storage unit 15, and the input and output interface 17 are connected to each other via an internal bus 16. The main storage unit 14 and the auxiliary storage unit 15 can be accessed from the processor 11.

An image sensor 20, a microphone 21, and a drive unit 22 are provided outside the data processing apparatus 10. The image sensor 20, the microphone 21, and the drive unit 22 are connected to the internal bus 16 via the input and output interface 17. The image sensor 20 is, for example, a CCD sensor or a CMOS sensor. The microphone 21 is, for example, the microphone 203 in FIG. 2. The drive unit 22 is, for example, the pan-tilt control unit 205, and the zoom unit and the focus unit of the image capturing unit 201 in FIG. 2.

The processor 11 controls an entire operation of the data processing apparatus 10. The processor 11 may be a CPU or a graphics processing unit (GPU). The processor 11 may be a single-core processor or a multi-core processor. The processor 11 may include a hardware circuit (for example, an FPGA or an ASIC) such as an accelerator that accelerates part of processing.

The main storage unit 14 may include a semiconductor memory such as a static random access memory (SRAM) or a dynamic random access memory (DRAM). The main storage unit 14 can store a program being executed by the processor 11 and include a work area for the processor 11 to execute a program.

The auxiliary storage unit 15 is a nonvolatile storage device such as a ROM, a hard disk device, or a solid state drive (SSD). The auxiliary storage unit 15 can store executable files of various programs and data to be used in execution of the programs. For example, the auxiliary storage unit 15 can store a data processing program 15A. The data processing program 15A may be software that can be installed in the camera 200, or may be incorporated in the camera 200 as firmware.

The communication control unit 12 is hardware having a function of controlling communication with the outside. The communication control unit 12 is connected to a network 19 via the communication interface 13. The network 19 may be the Internet, a wide area network (WAN), a local area network (LAN) such as Wireless Fidelity (Wi-Fi) or an Ethernet, or a mixture of the Internet, the WAN, and the LAN.

The input and output interface 17 converts data input from the image sensor 20, the microphone 21, and the drive unit 22 into data in a format that can be processed by the processor 11. Further, the input and output interface 17 converts data output from the processor 11 into data in a format that can be processed by the image sensor 20 or the drive unit 22.

The processor 11 reads the data processing program 15A stored in the auxiliary storage unit 15 into the main storage unit 14 and executes the data processing program 15A, and thus can implement sound data copy processing, sound data gain processing, and sound data analysis processing.

Execution of the program for implementing the sound data copy processing, the sound data gain processing, and the sound data analysis processing may be shared by a plurality of processors or computers. Alternatively, the processor 11 may instruct a cloud computer or the like via the network 19 to execute all or part of the program for implementing the sound data copy processing, the sound data gain processing, and the sound data analysis processing and may receive an execution result of the processing.

The present disclosure may supply a program for implementing one or more functions of the above-described exemplary embodiments to a system or an apparatus via a network or a storage medium. The one or more functions of the above-described exemplary embodiments can also be implemented by processing in which one or more processors in a computer of the system or the apparatus reads and executes the program. Further, the one or more functions of the above-described exemplary embodiments can also be implemented by a circuit (for example, an FPGA or an ASIC) for implementing the one or more functions. While the present disclosure has been described with reference to the exemplary embodiments, it is to be understood that the present disclosure is not limited to the disclosed exemplary embodiments and can be modified and changed in various ways within the scope of the appended claims.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2021-125989, filed Jul. 30, 2021, which is hereby incorporated by reference herein in its entirety.

What is claimed is:

1. A data processing apparatus comprising:
one or more processors; and
one or more memories including instructions stored thereon that, when executed by the one or more processors, cause the data processing apparatus to function as:
a copy unit configured to generate second sound data by copying first sound data; and
a processing unit configured to apply a first gain to at least one of the first sound data and the second sound data.

2. The data processing apparatus according to claim 1, further comprising:
a distribution unit configured to distribute the first sound data to which the first gain is applied by the processing unit; and
an analysis unit configured to analyze the second sound data to which the first gain is not applied by the processing unit.

3. The data processing apparatus according to claim 2,
wherein the processing unit includes a control unit configured to apply the first gain by automatic gain control (AGC) to the first sound data, and
wherein the second sound data is a copy of the first sound data copied before the first gain is applied to the first sound data.

4. The data processing apparatus according to claim 3, wherein the processing unit does not apply the first gain to the second sound data.

5. The data processing apparatus according to claim 2, wherein the processing unit stores a gain at a time of calibration as a second gain and applies the second gain to the second sound data to be used in the analysis unit.

6. The data processing apparatus according to claim 1,
wherein the processing unit includes a control unit configured to apply the first gain by AGC to the first sound data, and
wherein the data processing apparatus includes:
a distribution unit configured to distribute the first sound data to which the first gain is applied by the processing unit; and
an analysis unit configured to analyze the second sound data generated by copying the first sound data to which the first gain has been applied by the processing unit, the second sound data being applied with a negative gain canceling at least part of the first gain.

7. The data processing apparatus according to claim 1,
wherein the processing unit includes a control unit configured to apply the first gain by AGC to the first sound data,
wherein the data processing apparatus includes:
a distribution unit configured to distribute the first sound data to which the first gain is applied by the processing unit; and
an analysis unit configured to analyze the second sound data generated by copying the first sound data by the copy unit, and
wherein the processing unit changes a detection threshold of the second sound data in response to a change in the first gain.

8. The data processing apparatus according to claim 1,
wherein sound data output from a microphone is input to an image capturing apparatus, and
wherein the processing unit applies a negative gain to the second sound data in response to drive of a drive unit of the image capturing apparatus during operation of the drive unit.

9. A method for processing data, the method comprising:
generating second sound data by copying first sound data; and
applying a gain to at least one of the first sound data and the second sound data.

10. A non-transitory storage medium storing a program for causing a computer to execute a method for processing data, the method comprising:
generating second sound data by copying first sound data; and
applying a gain to at least one of the first sound data and the second sound data.
